(19) United States
(12) Patent Application Publication
(10) Pub. No.: US 2025/0062098 A1
(43) Pub. Date: Feb. 20, 2025

(54) SYSTEM AND METHOD FOR DYNAMIC ABERRATION CORRECTION

(71) Applicant: KLA Corporation, Milpitas, CA (US)

(72) Inventors: Xiaoxue Chen, Fremont, CA (US); Youfei Jiang, Milpitas, CA (US); Balaji Srinivasan, Chennai (IN); Arjun Hegde, Fremont, CA (US)

(21) Appl. No.: 18/424,069

(22) Filed: Jan. 26, 2024

(30) Foreign Application Priority Data
Aug. 18, 2023 (IN) 202341055374

(51) Int. Cl. H01J 37/153; H01J 37/147; H01J 37/244; H01J 37/28

(52) U.S. Cl. CPC H01J 37/153; H01J 37/147; H01J 37/244; H01J 37/28; H01J 2237/1534; H01J 2237/2448

(57) ABSTRACT

A method for dynamic aberration correction includes generating a primary electron beam with an electron beam source. The method includes directing the primary electron beams to a sample with an electron-optical column and deflecting the primary electron beam to an objective lens of the electron-optical column using a first Wien filter to correct for coma blur in the primary electron beam. The method includes generating off-axis chromatic aberration in the primary electron beam using the objective lens. The method includes adjusting one of a strength or orientation of the Wien filter to correct the off-axis chromatic aberration in the primary electron beam generated by the objective lens. The method includes detecting one or more secondary electrons emanating from the sample.

### CROSS-REFERENCE TO RELATED APPLICATIONS

The present application claims priority to India Provisional Patent Application No. 20/2341055374, filed Aug. 18, 2023, entitled Achievement of Extreme Large Field of View with Excellent Resolution Uniformity, naming Xiaoxue Chen, Youfei Jiang, Balaji Srinivasan, and Arjun Hedge as inventors, which is incorporated herein by reference in the entirety.

### TECHNICAL FIELD

The present disclosure relates generally to electron-optical systems and, more particularly, to aberration correction in an electron-optical system.

### BACKGROUND

As semiconductor device size becomes smaller, it becomes more critical to develop optical systems that compensate for aberrations. For example, such optical systems may include electron beam-based inspection systems, such as scanning electron microscopy (SEM) systems. Typical SEM systems include a lower Wien filter located within the electron-optical column and positioned above the sample for the purpose of deflecting the secondary electrons to a secondary electron detector. The utilization of the lower Wien filter for splitting secondary electrons from the primary electron beam may cause unidirectional chromatic aberrations in the primary electron beam due to the energy spread of the electron source. An upper Wien filter may be used to correct the lower Wien filter introduced chromatic aberrations using the unidirectional chromatic aberrations generated by the upper Wien filter.

However, when scanning a field of view (FOV) on a sample, the objective lens also generates aberrations (e.g., on-axis and off-axis aberrations). On-axis aberrations determine the fundamental spot size of the primary electron beam on the center of the FOV, while off-axis aberrations determine the spot size uniformity across the whole FOV. The spot size (i.e., resolution) uniformity across the whole FOV is important for defect sensitivity and measurement accuracy. Off-axis aberrations may include, but are not limited to, coma, transverse chromatic (TC) aberration, field curvature, and astigmatism. Field curvature and astigmatism blurs are correctable (e.g., using round lenses, quadruple lenses, or the like) since they are proportional to the square of the off-axis distance. However, coma and TC aberrations are uncorrectable since they are linearly proportional to the off-axis distance, such that the resolution uniformity of the FOV is limited.

Typically, existing SEM systems apply top-down TC correction by deflecting the beam back to the focal point of the objective lens to correct minimal coma, top-down TC blur and then apply the top-down TC correction to each site. However, such technique does not simultaneously correct coma and TC blur, rather top-down TC correction only minimizes top down TC blur. Further, due to the dynamic beam centering on each site, the lower magnetic field (MF) strength may vary, and TC blur may increase as the FOV increases, such that top down TC correction is not able to correct the off-axis TC blur completely. Further, due to tool alignment, the best resolution center might not be at the center of the FOV, which causes the MF center shift.

As such, it would be advantageous to provide a system and method for simultaneously minimizing both coma and TC blur that cures the shortcomings of the previous approaches identified above.

### SUMMARY

An electron-optical system is disclosed, in accordance with one or more embodiments of the present disclosure. In embodiments, the electron-optical system includes an electron beam source configured to generate a primary electron beam. In embodiments, the electron-optical system includes an electron-optical column including a set of electron-optical elements configured to direct at least a portion of the primary electron beam onto a portion of a sample. In embodiments, the set of electron-optical elements include an objective lens disposed along an optical axis. In embodiments, the set of electron-optical elements include a first deflector assembly disposed along the optical axis, where the first deflector assembly includes a first Wien filter. In embodiments, the set of electron-optical elements include a second deflector assembly disposed along the optical axis, where the second deflector assembly includes a second Wien filter, where the first Wien filter of the first deflector assembly is configured to deflect the primary electron beam to a point on the objective lens to minimize coma blur, where the objective lens generates off-axis chromatic aberration upon minimizing the coma of the primary electron beam, where the first Wien filter of the first deflector assembly is configured to correct the off-axis chromatic aberration in the primary electron beam generated by the objective lens. In embodiments, the electron-optical system includes a detector assembly configured to detect secondary electrons emanating from the sample.

An electron-optical system is disclosed, in accordance with one or more embodiments of the present disclosure. In embodiments, the electron-optical system includes a controller communicatively coupled to a deflector assembly and a detector assembly. In embodiments, the controller includes one or more processors configured to cause a set of program instructions to: direct a first Wien filter of a first deflector assembly to deflect a primary electron beam to an objective lens within an electron-optical column to correct coma blur, where the objective lens generates off-axis chromatic aberration upon minimizing the coma of the primary electron beam; adjust one of a strength or orientation of the first Wien filter to correct the off-axis chromatic aberration in the primary electron beam generated by the objective lens; adjust a beam voltage of an electron beam source to amplify an energy source spread of the electron beam source; and receive a sample image of the sample from a detector assembly to verify aberration correction in the primary electron beam, where the detector assembly generates the sample image of the sample based on the adjusted beam voltage.

A method for dynamic aberration correction is disclosed, in accordance with one or more embodiments of the present disclosure. In embodiments, the method includes generating a primary electron beam with an electron beam source. In embodiments, the method includes directing the primary electron beams to a sample with an electron-optical column. In embodiments, the method includes deflecting the one or more primary electron beams to an objective lens of the electron-optical column using a first Wien filter to correct coma blur in the primary electron beam. In embodiments, the method includes generating off-axis chromatic aberration in the primary electron beam using the objective lens. In embodiments, the method includes adjusting one of a strength or orientation of the Wien filter to correct the off-axis chromatic aberration in the primary electron beam generated by the objective lens. In embodiments, the method includes detecting one or more secondary electrons emanating from the sample.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A is a simplified schematic view of an electron-beam optical system, in accordance with one or more embodiments of the present disclosure.

FIG. 1B is a simplified schematic view of an electron-beam optical system, in accordance with one or more embodiments of the present disclosure.

FIG. 2A is a diagram depicting Wien-induced TC blur caused by a Wien Filter, in accordance with one or more embodiments of the present disclosure.

FIG. 2B is a diagram depicting Wien-induced TC blur correction, in accordance with one or more embodiments of the present disclosure.

FIG. 3A is a diagram depicting TC blur caused by an WF2 and objective lens when scanning a FOV, in accordance with one or more embodiments of the present disclosure.

FIG. 3B is a diagram depicting TC blur correction by WF1 when scanning a large FOV, in accordance with one or more embodiments of the present disclosure.

FIG. 4 is a flow chart depicting a method for aberration correction in an electron-beam optical system, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a system and method for dynamic aberration correction. Embodiments of the present disclosure are directed to a system and method for dynamic aberration correction of off-axis objective lens-induced aberrations. For example, the system may include a dual-deflector assembly, including dual Wien filters, configured to simultaneously minimize coma blur and correct leftover TC blur across the FOV. As such, a large FOV (e.g., up to 1 mm FOV) and good resolution uniformity across the FOV may be achieved, such that defect sensitivity and measurement accuracy are improved in the system.

Additionally, embodiments of the present disclosure are directed to a system and method for verifying and calibrating aberration correction. For example, the system and method may amplify the source energy spread of the electron beam at each site to determine whether a respective aberration has been substantially corrected and minimize the beam shift at each site. As such, the resolution uniformity of the main field may be improved.

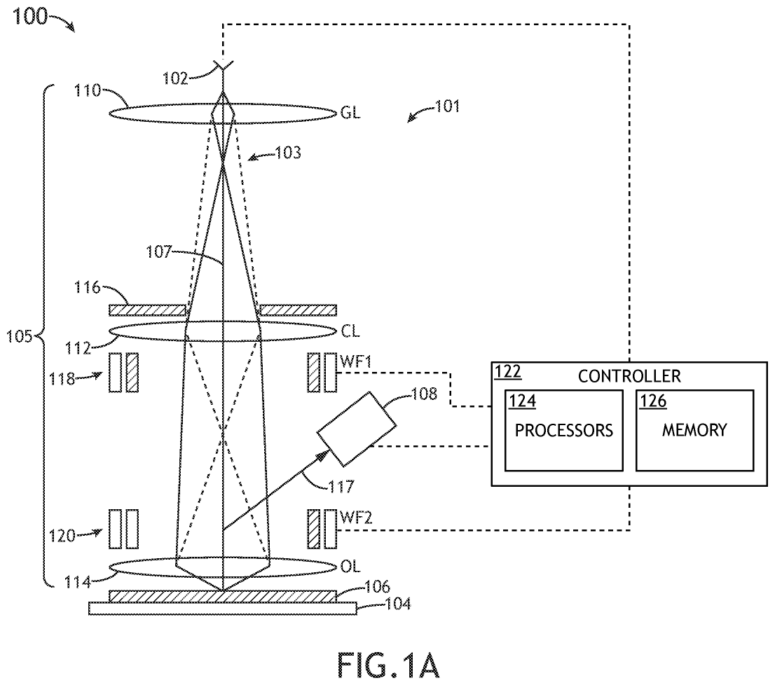

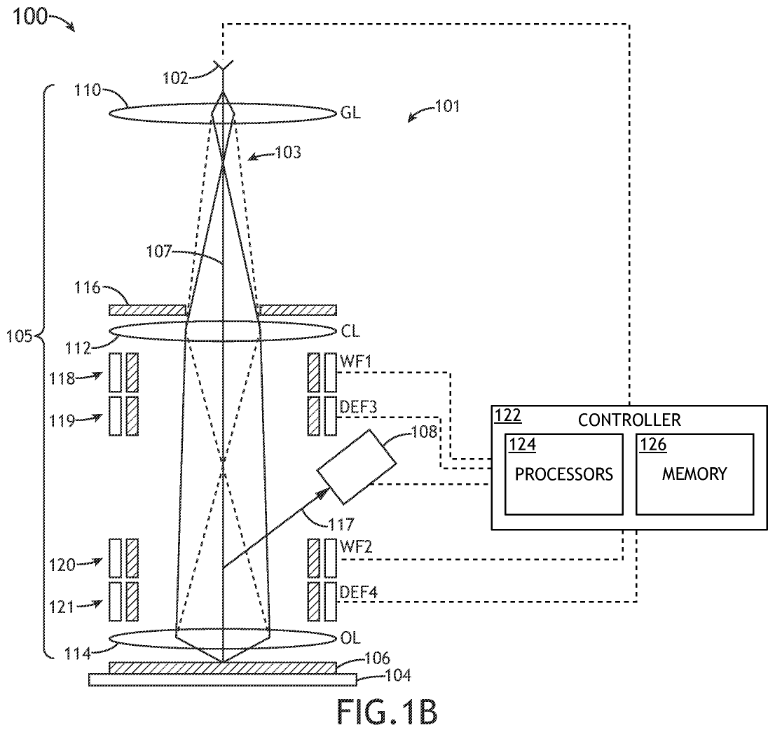

FIGS. 1A-1B illustrate an electron-optical system 100 arranged for performing SEM imaging, review and/or inspection, in accordance with one or more embodiments of the present disclosure. An electron-optical system is generally described in U.S. Pat. No. 10,224,177, issued on Mar. 5, 2019, and U.S. Pat. No. 10,090,131, issued on Oct. 2, 2018, which are each incorporated herein by reference in the entirety.

In embodiments, the electron-optical system 100 includes, but is not limited to, an electron-optical column 101, an electron beam source 102 configured to generate a primary electron beam 103, a stage 104 configured to secure a sample 106, a detector assembly 108, and a controller 122. In embodiments, the electron-optical column 101 includes a set of electron-optical elements 105. The set of electron-optical elements 105 may include, but are not limited to, a gun lens 110, condenser lens 112, and an objective lens (OL) 114 disposed along an optical axis 107 (e.g., z-axis, as shown in FIGS. 1A-1B).

In embodiments, the electron-optical column 101 includes a first deflector assembly 118 and a second deflector assembly 120. For example, the first deflector assembly 118 and the second deflector assembly 120 may each be Wien filters. For the purposes of the present disclosure, the first deflector assembly 118 may be referred to as the first Wien filter 118 (WF1) and the second deflector assembly 120 may be referred to as the second Wien filter 120 (WF2).

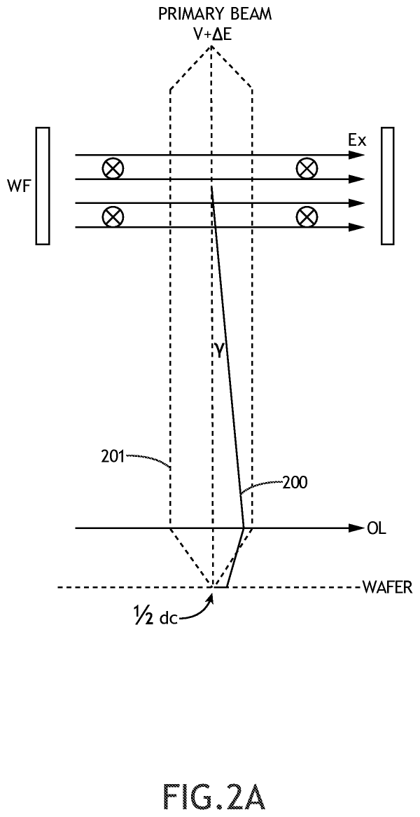

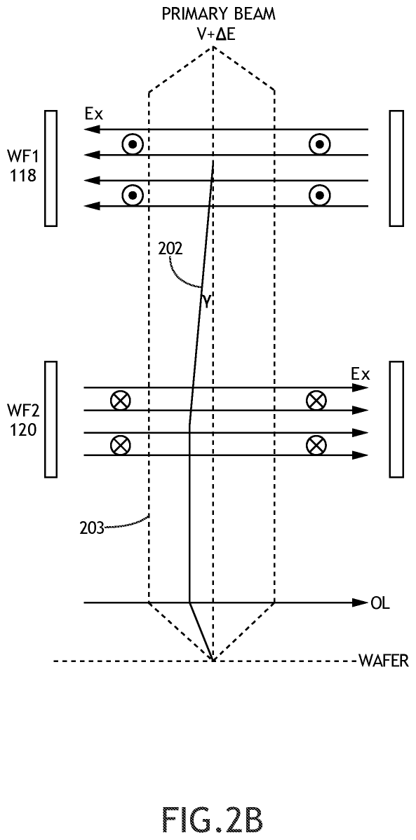

FIG. 2A illustrates Wien-induced TC blur caused by a lower Wien Filter. For example, as shown in FIG. 2A, the lower Wien filter may cause unidirectional chromatic aberrations (d_{C}) in the primary electron beam due to the energy spread (ΔE) of the electron source energy (V). For instance, FIG. 2A depicts the primary beam trajectory 200, having a beam energy (E) and a primary dispersion angle from the combination of Wien Filter electric-field and magnetic-field (Y), and focusing of paraxial ray without Wien Filter 201, resulting in unidirectional chromatic aberrations (d_{C}) in the primary electron beam.

FIG. 2B is a diagram depicting Wien-induced TC blur correction, in accordance with one or more embodiments of the present disclosure. In embodiments, the first Wien filter 118 (WF1) may be configured to correct axial chromatic aberration in the primary beam 103 caused by the second Wien filter 120 (WF2) (i.e., Wien filter induced chromatic aberration). For example, the first Wien filter 118 may be positioned above the detector assembly 108. For instance, FIG. 2B depicts the primary beam trajectory 202, having a beam energy (E) and a primary dispersion angle from the combination of Wien Filter electric-field and magnetic-field (γ), and focusing of paraxial ray without Wien Filter 203, resulting in correction of axial chromatic aberrations (d_{C}) in the primary electron beam. Correction of axial chromatic aberration induced by the second Wien filter 120 is generally discussed in U.S. Pat. No. 10,224,177, issued on Mar. 5, 2019, and U.S. Pat. No. 10,090,131, issued on Oct. 2, 2018, which are each incorporated herein by reference in the entirety.

In embodiments, the first Wien filter 118 is configured to correct off-axis aberrations generated by the objective lens 114. For example, the first Wien filter 118 may be configured to simultaneously correct coma and TC aberrations in the primary beam 103 generated by the objective lens 114.

In embodiments, the first Wien filter 118 is configured to correct coma in the primary beam 103 by deflecting the primary beam 103 to a point of the objective lens 114 where coma blur is minimized. For example, the first Wien filter 118 may act as a deflector to deflect the beam through a wobble-free point of the objective lens 114 where coma blur is minimized.

In embodiments, the first Wien filter 118 is configured to correct off-axis TC blur in the primary beam 103 generated by the objective lens 114. For example, the objective lens 114 may generate off-axis TC (i.e., post-coma TC), as such, when minimizing coma blur at the objective lens, the objective lens 114 further generates off-axis TC.

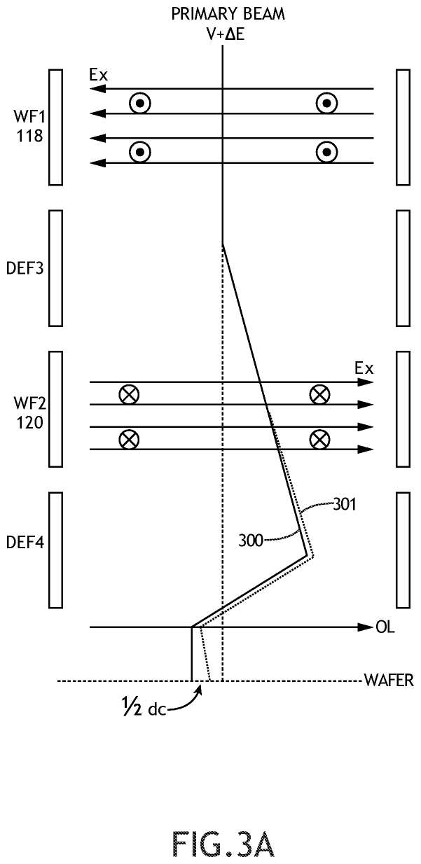

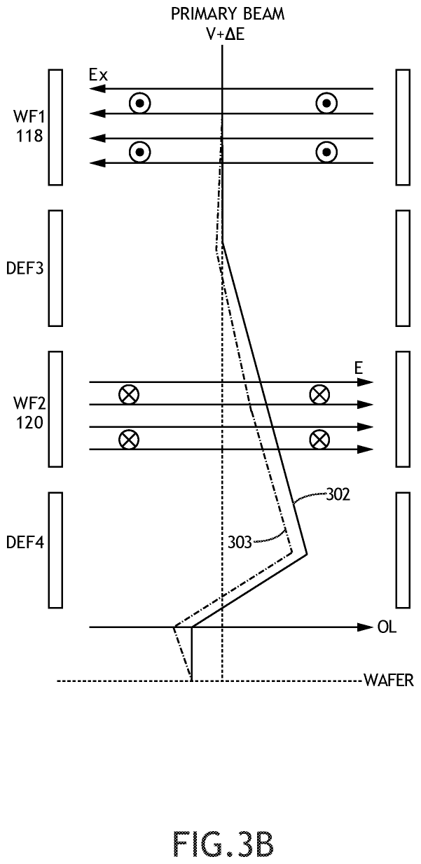

FIG. 3A illustrates TC blur caused by an objective lens and WF2. It is contemplated herein that axial TC blur introduced by the Wien filter may be directional, while off-axis TC blur generated by the objective lens may be rotationally symmetric (as shown in FIG. 3A). In this regard, the magnitude of the off-axis TC blur introduced by the objective lens may be proportional to the off-axis distance. For instance, FIG. 3A depicts the primary beam trajectory 300 deflected by DEF3 and DEF4 without WF and primary beam trajectory 301 deflected to a certain FOV by DEF3 and DEF4 with WF2 120, resulting in chromatic aberration blur (d_{C}). FIG. 3B illustrates TC blur correction, in accordance with one or more embodiments of the present disclosure. For instance, FIG. 3B depicts the primary beam trajectory 302 deflected to a certain FOV by DEF3 and DEF4 without WF and primary beam trajectory 303 deflected to a certain FOV by DEF3 and DEF4 with TC correction from WF1 118, resulting in the correction of chromatic aberration blur (d_{C}).

In embodiments, the strength and/or orientation of the first Wien filter 118 may be dynamically adjusted to correct the rotationally symmetric off-axis TC blur generated by the objective lens and WF2 to enable a large FOV (e.g., up to approximately 1 mm) with excellent resolution uniformity (i.e., increased spot size).

In embodiments, the second Wien filter 120 is configured to direct the secondary electrons (SE) 117 emitted by the sample 106 (in response to the primary beam 103) to the detector assembly 108. In this regard, the system 100 may correct for aberrations in the primary electron beam 103, while simultaneously splitting the secondary electrons 117 from the beam of primary electrons 103 for collection by the detector assembly 108.

It is noted that the first Wien filter 118 and the second Wien filter 120 may be placed at any position along the optical axis 107 and achieve simultaneous correction of coma and chromatic aberrations of system 100. For example, the first Wien filter 118 and the second Wien filter 120 may both be disposed between the gun lens 110 and the objective lens 114. For instance, as shown in FIGS. 1A-1B, the first Wien filter 118 and the second Wien filter 120 may be both disposed between the condenser lens 112 and the objective lens 114. In this regard, the second Wien filter 120 may be placed in close proximity to the objective lens 114 in order to deflect the secondary electrons 117 towards the detector assembly 108 for collection. The first Wien filter 118 may be placed below the condenser lens 112 and is used to correct coma and chromatic aberrations in the primary beam 103 induced by the objective lens 114.

In embodiments, the electron-optical column 101 includes a third deflector assembly 119 and a second deflector assembly 121. For example, as shown in FIG. 1B, when scanning an extremely large FOV (e.g., 1 mm), the electron-optical column 101 may include the third deflector assembly 119 and the second deflector assembly 121. For instance, the third deflector assembly 119 may be positioned between the first Wien Filter 118 and the second Wien Filter 120, but above the detector assembly 118 and the fourth deflector assembly 121 may be positioned below the second Wien Filter 120 but above the objective lens 114.

In embodiments, the controller 122 may be communicatively coupled to the detector assembly 108 and/or various components of the electron-optical system 100 (e.g., one or more of the first deflector assembly 118, the second deflector assembly 120, the third deflector assembly 119, the fourth deflector assembly 121, the electron source 102, or the like). In this regard, the controller 122 may direct any of the components of system 100 to carry out any one or more of the various functions described previously herein. For example, the controller 122 may direct the first Wien filter 118 of the first deflector assembly 118 to deflect the primary beam 103 to a point on the objective lens 114 to minimize coma blur. By way of another example, the controller 122 may adjust one of a strength or orientation of the first Wien filter 118 of the first deflector assembly 118 to correct objective lens induced chromatic aberration in the primary beam 103. By way of another example, the controller 122 may adjust a beam voltage of the electron source 102 to amplify the source energy spread of the primary beam 103 at each magnetic field site, such that aberration correction may be verified and/or calibrated.

The electron beam source 102 may include any electron source known in the art. For example, the electron beam source 102 may include, but is not limited to, one or more electron guns (e.g., emitter/emission tip). For instance, the electron beam source 102 may include a single electron gun for generating a single electron beam 103.

The sample 106 may include any sample suitable for inspection/review with electron-beam microscopy, such as, but not limited to, a substrate. For example, the substrate may include, but is not limited to, a semiconductor wafer.

In embodiments, the sample stage 104 is an actuatable stage. For example, the sample stage 104 may include, but is not limited to, one or more translational stages suitable for selectably translating the sample 106 along one or more linear directions (e.g., x-direction, y-direction and/or z-direction). By way of another example, the sample stage 104 may include, but is not limited to, one or more rotational stages suitable for selectively rotating the sample 106 along a rotational direction. By way of another example, the sample stage 104 may include, but is not limited to, a rotational stage and a translational stage suitable for selectably translating the sample 106 along a linear direction and/or rotating the sample 106 along a rotational direction.

It is noted herein that the system 100 may operate in any scanning mode known in the art. For example, the system 100 may operate in a swathing mode when scanning the primary electron beam 103 across the surface of the sample 106. In this regard, the system 100 may scan the primary electron beam 103 across the sample 106, while the sample is moving, with the direction of scanning being nominally perpendicular to the direction of the sample motion. By way of another example, the system 100 may operate in a step-and-scan mode when scanning the primary electron beam 103 across the surface of the sample 106. In this regard, the system 100 may scan the primary electron beam 103 across the sample 106, which is nominally stationary when the beam 103 is being scanned.

In embodiments, the detector assembly 108 is configured to collect secondary and/or backscattered electrons (hereinafter referred to as “secondary electrons” for simplicity) emanated from the surface of the sample 106 in response to the primary electron beam 103.

For example, the detector assembly 108 may be a secondary electron detector. It is noted that that the detector assembly 108 may include any type of electron detector known in the art. For example, the detector assembly 108 may include a scintillator-based detector for collecting secondary electrons from the sample 106, such as, but not limited to, an Everhart-Thornley detector. By way of another example, the detector assembly 108 may include a micro-channel plate (MCP) for collecting secondary electrons from the sample 106. By way of another example, the detector assembly 108 may include a PIN or p-n junction detector, such as a diode or a diode array, for collecting secondary electrons from the sample 106. By way of another example, the detector assembly 108 may include one or more avalanche photo diodes (APDs) for collecting secondary electrons from the sample 106.

In embodiments, the set of electron-optical elements 105 may direct at least a portion of the primary electron beam 103 onto a selected portion of the sample 106. The set of electron-optical elements 105 may include any electron-optical elements known in the art suitable for focusing and/or directing the primary electron beam 103 onto a selected portion of the sample 106. For purposes of simplicity, a single electron-optical column is depicted in FIGS. 1A-1B. It is noted herein that this configuration should not be interpreted as a limitation on the scope of present disclosure. For example, the system 100 may include multiple electron-optical columns.

In embodiments, the electron-optical column 101 includes an aperture 116. The aperture 116 may be used to select the beam currents of the system 100 for various uses. For example, the aperture 116 may be positioned between the gun lens 110 and the condenser lens 112. The strength of the gun lens 110 may be varied to select various beam currents via the aperture 116, and the strength of the condenser lens 112 may be varied to select an optimal numerical aperture (NA) at the sample 106 so as to form an image that has adequate quality and resolution. In cases where multiple apertures are used to select the beam current of the system 100, only the gun lens 110 and objective lens 114 may be required to form the image at the sample 106 because the multiple aperture sizes may already be designed to select the optimal NA.

It is noted herein that although FIGS. 1A-1B depict a specific configuration of electron-optical elements 105, such depiction is provided merely for illustrative purposes and shall not be construed as limiting the scope of the present disclosure. The electron-optical elements 105 may be in any configuration suitable for directing the primary electron beams to the surface of the sample.

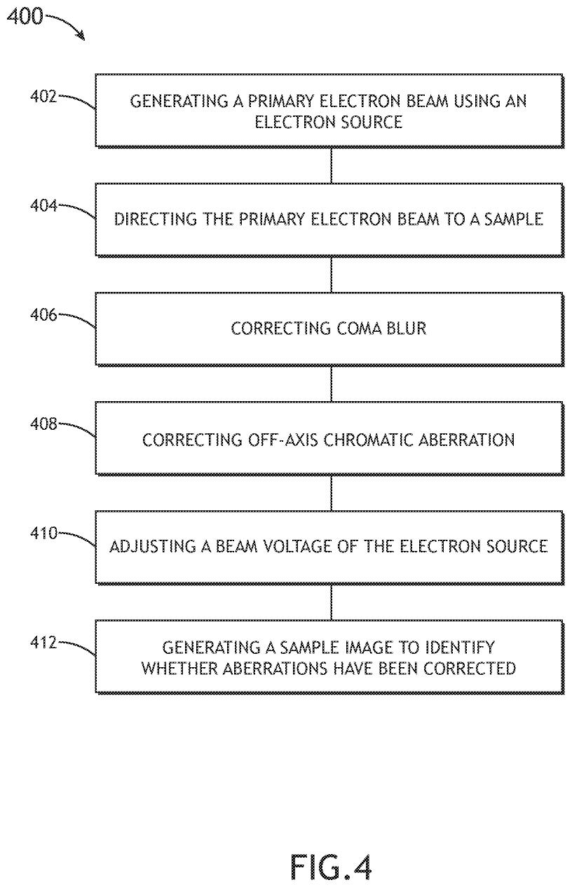

FIG. 4 illustrates a flowchart of a method 400 for operating an electron-beam optical system 100, in accordance with one or more embodiments of the present disclosure. It is noted herein that the steps of method 400 may be implemented all or in part by electron-beam optical system 100. It is further recognized, however, that the method 400 is not limited to the electron-beam optical system 100 in that additional or alternative system-level embodiments may carry out all or part of the steps of method 400.

In a step 402, one or more primary electron beams are generated with an electron beam source. For example, as shown in FIGS. 1A-1B, the electron beam source 102 is configured to generate one or more primary electron beams 103 and direct the one or more primary electron beams 103 to the sample 106. The electron beam source 102 may include any electron beam source known in the art including, but not limited to, electron guns, photocathode electron beam sources, and the like.

In a step 404, the one or more primary electron beams are directed to a sample with an electron-optical column. For example, the electron-optical column may include one or more electron-optical elements 105 configured to receive the one or more primary electron beams 103 and direct the one or more primary electron beams 103 to the sample 106. The one or more electron-optical elements 105 may include any electron-optical elements known in the art including, but not limited to, extractors, beam-limiting apertures, deflectors, electron-optical lenses, condenser lenses (e.g., magnetic condenser lenses), objective lenses (e.g., magnetic condenser lenses), and the like.

In a step 406, coma blur is corrected. For example, the one or more primary electron beams may be deflected to a point on the objective lens where coma blur is minimized. For instance, the first Wien filter 118 may be configured to deflect the one or more primary electron beams 103 to a point on the objective lens 114 where coma blur is minimized.

In a step 408, objective lens induced off-axis chromatic aberration is corrected. For example, the first Wien filter 118 may correct for off-axis chromatic aberration in the primary beam 103 generated by the objective lens 114 (in step 406). For instance, the controller may adjust one of a strength or orientation of the electric and/or magnetic fields of the first Wien filter 118 to correct for the chromatic aberration in the primary electron beam 103.

In a step 410, the electron source energy spread is adjusted. For example, the energy spread of the electron beam source 102 may be adjusted to amplify the source spread. For instance, the controller 122 may adjust the beam voltage of the electron beam source 102 to amplify the spread.

The beam voltage of the electron beam source 102 may be adjusted by any suitable amount. For example, the beam voltage may be adjusted by approximately +/−5 to 10 V. By way of another example, the beam voltage may be adjusted by approximately +/−20 V.

It is contemplated herein that without amplifying the integer spread, it is difficult to identify TC on the sample image since the integer spread is normally +/−1 V. However, by adjusting the beam voltage, the integer spread is amplified such that it is easier to identify whether TC has been fully compensated for on the sample image.

In a step 412, a sample image is generated based on the adjusted beam voltage. For example, the controller 122 may be configured to receive an image of the sample 106 from the detector assembly 108. In this regard, the sample image of the sample 106 may be used to determine whether aberrations have been fully correction.

Upon determining aberrations have not been fully corrected, one or more of steps of the method 400 may be repeated until the aberrations have been substantially corrected. For example, steps 408-412 may be repeated until the aberrations have been substantially corrected.

It is noted herein that the one or more components of electron-beam optical system 100 may be communicatively coupled to the various other components of electron-beam optical system 100 in any manner known in the art. For example, the one or more processors 124 may be communicatively coupled to each other and other components of the electron-beam optical system 100 via a wireline (e.g., copper wire, fiber optic cable, and the like) or wireless connection (e.g., RF coupling, IR coupling, data network communication, WiFi, WiMax, Bluetooth, 3G, 4G, 4G LTE, 5G, and the like).

In embodiments, the one or more processors 124 may include any processing element known in the art. In this sense, the one or more processors 124 may include any microprocessor-type device configured to execute software algorithms and/or instructions. In embodiments, the one or more processors 124 may consist of a desktop computer, mainframe computer system, workstation, image computer, parallel processor, or other computer system (e.g., networked computer) configured to execute a program configured to operate the electron-beam optical system 100, as described throughout the present disclosure. It should be recognized that the steps described throughout the present disclosure may be carried out by a single computer system or, alternatively, multiple computer systems. In general, the term “processor” may be broadly defined to encompass any device having one or more processing elements, which execute program instructions from memory 126. Moreover, different subsystems of the electron-beam optical system 100 (e.g., electron beam source 102, electron-optical column, detector 108, controller 122) may include processor or logic elements suitable for carrying out at least a portion of the steps described throughout the present disclosure. Therefore, the above description should not be interpreted as a limitation on the present disclosure but merely an illustration.

The memory 126 may include any storage medium known in the art suitable for storing program instructions executable by the associated one or more processors 124 and/or images received from the detector 108. For example, the memory 126 may include a non-transitory memory medium. For instance, the memory 126 may include, but is not limited to, a read-only memory (ROM), a random-access memory (RAM), a magnetic or optical memory device (e.g., disk), a magnetic tape, a solid-state drive and the like. It is further noted that memory 126 may be housed in a common controller housing with the one or more processors 124. In embodiments, the memory 126 may be located remotely with respect to the physical location of the processors 124, controller 122, and the like. In embodiments, the memory 126 maintains program instructions for causing the one or more processors 124 to carry out the various steps described through the present disclosure.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An electron-optical system, the electron-optical system comprising:
an electron beam source configured to generate a primary electron beam;
an electron-optical column including a set of electron-optical elements configured to direct at least a portion of the primary electron beam onto a portion of a sample, the set of electron-optical elements comprising:
an objective lens disposed along an optical axis;
a first deflector assembly disposed along the optical axis, wherein the first deflector assembly includes a first Wien filter; and
a second deflector assembly disposed along the optical axis, wherein the second deflector assembly includes a second Wien filter,
wherein the first Wien filter of the first deflector assembly is configured to deflect the primary electron beam to a point on the objective lens to minimize coma blur, wherein the objective lens generates off-axis chromatic aberration upon minimizing the coma of the primary electron beam,
wherein the first Wien filter of the first deflector assembly is configured to correct the off-axis chromatic aberration in the primary electron beam generated by the objective lens; and
a detector assembly configured to detect secondary electrons emanating from the sample.

2. The electron-optical system of claim 1, wherein the off-axis chromatic aberration is rotationally symmetric.

3. The electron-optical system of claim 1, further comprising:
a controller communicatively coupled to the detector assembly, the controller including one or more processors configured to execute a set of program instructions stored in memory.

4. The electron-optical system of claim 3, wherein the set of program instructions are configured to cause the one or more processors to:
direct the first Wien filter of the first deflector assembly to deflect the primary electron beam to the point on the objective lens within the electron-optical column to correct for the coma blur; and
adjust one of a strength or orientation of the first Wien filter of the first deflector assembly to correct the off-axis chromatic aberration in the primary electron beam generated by the objective lens.

5. The electron-optical system of claim 3, wherein the set of program instructions are configured to cause the one or more processors to:
adjust a beam voltage of the electron beam source to amplify an energy source spread of the electron beam source; and
generate a sample image of the sample based on the adjusted beam voltage to identify existing aberration in the primary electron beam.

6. The electron-optical system of claim 1, wherein the second Wien filter of the second deflector assembly is configured to direct the secondary electrons emanating from the sample to the detector assembly.

7. The electron-optical system of claim 6, wherein the first Wien filter of the first deflector assembly is configured to correct axial chromatic aberration in the primary electron beam caused by the second Wien filter.

8. The electron-optical system of claim 1, wherein the electron beam source comprises:
one or more electron guns.

9. The electron-optical system of claim 1, wherein the detector assembly comprises:
one or more secondary electron detectors.

10. The electron-optical system of claim 1, wherein the electron-optical system is a scanning electron microscopy system.

11. An electron-optical system, the electron-optical system comprising:
a controller communicatively coupled to a deflector assembly and a detector assembly, the controller including one or more processors configured to cause a set of program instructions to:
direct a first Wien filter of a first deflector assembly to deflect a primary electron beam to an objective lens within an electron-optical column to correct coma blur, wherein the objective lens generates off-axis chromatic aberration upon minimizing the coma of the primary electron beam;
adjust one of a strength or orientation of the first Wien filter to correct the off-axis chromatic aberration in the primary electron beam generated by the objective lens;
adjust a beam voltage of an electron beam source to amplify an energy source spread of the electron beam source; and
receive a sample image of the sample from a detector assembly to verify aberration correction in the primary electron beam, wherein the detector assembly generates the sample image of the sample based on the adjusted beam voltage.

12. The electron-optical system of claim 11, wherein the off-axis chromatic aberration is rotationally symmetric.

13. The electron-optical system of claim 11, wherein a second Wien filter of a second deflector assembly is configured to direct secondary electrons emanating from the sample to the detector assembly.

14. The electron-optical system of claim 13, wherein the first Wien filter of the first deflector assembly is configured to correct axial chromatic aberration in the primary electron beam caused by the second Wien filter of the second deflector assembly.

15. A method comprising:
generating a primary electron beam with an electron beam source;
directing the primary electron beams to a sample with an electron-optical column;
deflecting the primary electron beam to an objective lens of the electron-optical column using a first Wien filter to correct for coma blur in the primary electron beam;
generating off-axis chromatic aberration in the primary electron beam using the objective lens;
adjusting one of a strength or orientation of the Wien filter to correct the off-axis chromatic aberration in the primary electron beam generated by the objective lens; and
detecting one or more secondary electrons emanating from the sample.

16. The method of claim 15, further comprising:
adjusting a beam voltage of the electron beam source to amplify an energy source spread of the electron beam source.

17. The method of claim 15, further comprising:
directing the one or more secondary electrons emanating from the sample to a detector assembly using a second Wien filter of a second deflector assembly.

18. The method of claim 17, further comprising:
correcting axial chromatic aberration in the primary electron beam caused by the second Wien filter of the second deflector assembly using the first Wien filter of a first deflector assembly.
